(19) United States
(12) Patent Application Publication
(10) Pub. No.: US 2009/0108450 A1
(43) Pub. Date: Apr. 30, 2009

(54) INTERCONNECT STRUCTURE AND METHOD OF MAKING SAME

(75) Inventors: James R. LLOYD, JR., Katonah, NY (US); Shom Ponoth, Clifton Park, NY (US); Terry A. Spooner, Clifton Park, NY (US); Chih-Chao Yang, Glenmont, NY (US)

Correspondence Address: GREENBLUM & BERNSTEIN, P.L.C., 1950 ROLAND CLARKE PLACE, RESTON, VA, 20191, US

(73) Assignee: INTERNATIONAL BUSINESS MACHINES CORPORATION, Armonk, NY (US)

(21) Appl. No.: 11/928,327

(22) Filed: Oct. 30, 2007

(51) Int. Cl. H01L 23/52

(52) U.S. Cl. 257/751; 257/E23.141

(57) ABSTRACT

An interconnect structure and method of fabricating the same is provided. The interconnect structure is a highly reliable copper interconnect structure. The interconnect structure includes a planarized lower dielectric layer and a lower cap layer on the planarized lower dielectric layer. A copper material is formed in a trench of the planarized lower dielectric layer, below the lower cap layer. A lower liner extends into a pattern of the lower cap layer and contacts the copper layer. An upper dielectric layer is on the lower cap layer and a copper layer contacts the lower liner and is formed in a via of at least the lower cap layer. An upper liner is formed over the copper layer, sandwiching the copper layer between the lower liner and the upper liner. An upper copper layer is formed over the upper liner.

### FIELD OF THE INVENTION

The present invention relates generally to an interconnect structure and method of fabricating the same and, more particularly, to a highly reliable copper interconnect structure and method of fabricating the same.

### BACKGROUND OF THE INVENTION

The current density in interconnect structures increases due to scaling of the structures. This increased current density degrades EM (electromigration) related reliability. More specifically, the effect of electromigration becomes an increasing concern as the size of the IC decreases. Electromigration is the transport of material caused by the gradual movement of ions in a conductor due to the momentum transfer between conducting electrons and diffusing metal atoms. The effect of electromigration is an important consideration to take into account in applications where high direct current densities are used, such as in microelectronics and related structures. In fact, electromigration is known to decrease the reliability of an integrated circuits (ICs) and hence lead to a malfunction of the circuit. In the worst case, for example, electromigration leads to the eventual loss of one or more connections and intermittent failure of the entire circuit.

As such, as the structure size in ICs decreases, the practical significance of the EM effect increases. Thus, with increasing miniaturization the probability of failure due to electromigration increases in VLSI and ULSI circuits because both the power density and the current density increase. Also, it is know that in advanced semiconductor manufacturing processes, copper is used as the interconnect material. Basically, copper is preferred for its superior conductivity. However, for conventional structures, the copper and dielectric interface remains the weakest interface with regard to electromigration failures.

Accordingly, there exists a need in the art to overcome the deficiencies and limitations described hereinabove.

### SUMMARY OF THE INVENTION

In a first aspect of the invention, an interconnect structure comprises a planarized lower dielectric layer and a lower cap layer on the planarized lower dielectric layer. A copper material is formed in a trench of the planarized lower dielectric layer, below the lower cap layer. A lower liner extends into a pattern of the lower cap layer and contacts the copper layer. An upper dielectric layer is on the lower cap layer and a copper layer contacts the lower liner and is formed in a via of at least the lower cap layer. An upper liner is formed over the copper layer, sandwiching the copper layer between the lower liner and the upper liner. An upper copper layer is formed over the upper liner.

In another aspect of the invention, an interconnect structure comprises: a lower dielectric layer; a copper wire formed in a trench of the lower dielectric layer; a lower cap layer formed over the lower dielectric layer and the copper wire to form an M layer; an upper dielectric layer formed on the lower cap layer; a lower metal liner formed in a via of the lower cap layer and the upper dielectric layer and in contact with the copper wire; a copper layer deposited over the lower metal liner and in a trench of the upper dielectric layer, the copper layer being separated from the copper wire by the lower metal liner; an upper metal liner deposited over the copper layer and sandwiching the copper layer between the lower metal liner and the upper metal liner; an upper copper layer formed in the trench of the upper dielectric layer and in contact with the upper metal liner, the upper copper layer being separated from the copper layer by the upper metal liner; and an upper cap layer formed over the upper copper layer and the upper dielectric layer.

### BRIEF DESCRIPTION OF THE DRAWINGS

The present invention is described in the detailed description which follows, in reference to the noted plurality of drawings by way of non-limiting examples of exemplary embodiments of the present invention, in which:

FIGS. 1 and 2 show structures and respective fabrication processes in accordance with the invention; and

FIG. 3 shows a process flow in accordance with the invention.

### DETAILED DESCRIPTION OF EMBODIMENTS OF THE INVENTION

The present invention relates generally to an interconnect structure and method of fabricating the same and, more particularly, to a highly reliable copper interconnect structure and method of fabricating the same. By implementing the structure in accordance with the invention, the copper interconnect is more reliable than conventional systems and hence is not prone to failure to electromigration effects (e.g., higher electromigration resistance and lifetime). For example, advantageously, by implementing the fabrication process and structure in accordance with the invention, the copper interconnect includes a redundant liner, which prevents voids from forming in an underlying metal (copper) layer. Thus, in the structure of the present invention, the metal (copper) beneath the redundant liner maintains it connectivity and reliability even when the metal (copper) layer above the redundant liner begins to migrate and create voids. In this way, even when the voids grow in an upper layer, the interconnect as a system does not cause any disconnection failure, e.g., electromigration open failure, because the lower layer of the interconnect keeps the conductivity.

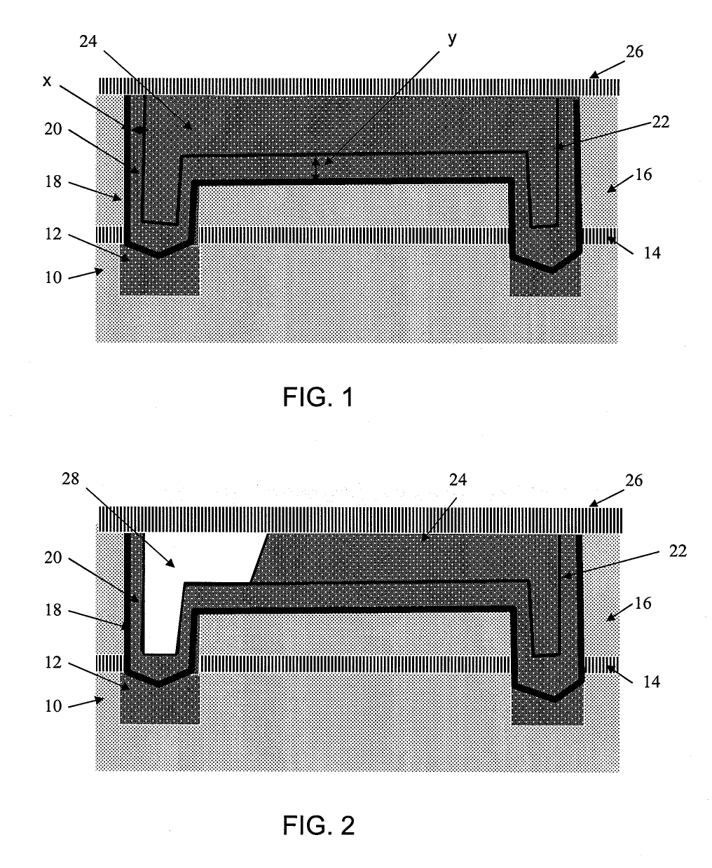

FIG. 1 shows a final structure and respective fabrication processes in accordance with the invention. More specifically, FIG. 1 shows a structure having a lower dielectric layer 10. The lower dielectric layer 10 can be, for example, any low k or ultra low k material such as, for example, silicon oxide, SiCxOyHz In embodiments, the lower dielectric layer 10 may have a thickness ranging from, for example, about 500 Å to 10000 Å.

A metal (e.g., copper) wire 12 is formed in a trench of the lower dielectric layer 10 using a conventional processes. For example, in a conventional process, a photoresist layer (not shown) is formed over the lower dielectric layer 10 and exposed to form a pattern (using a hard mask). The photoresist layer may be, for example, an organic spin on layer. A reactive ion etching (RIE) process is performed to form a trench in the lower dielectric layer 10. A metal (e.g., copper) material is deposited into the trench to form the conductive wire 12 (e.g., copper wire). The structure is then planarized using a conventional process such as a chemical mechanical processing (CMP).

A lower cap layer 14 is formed over the planarized lower dielectric layer 10 and the conductive wire 12 to form an M layer. The lower cap layer 14 may be made from any conventional capping material such as, for example, silicon nitride or silicon carbide. The lower cap layer 14 can have a thickness that ranges from about 50 Å to 1000 Å.

An upper dielectric layer 16 is deposited over the lower cap layer 14, in a conventional process. In embodiments, the upper dielectric layer 16 may have a thickness ranging from, for example, about 500 Å to 10000 Å. A via is formed in the upper dielectric layer 16 using a conventional lithographic and etching process. For example, a photoresist (not shown) is formed over the upper dielectric layer 16 and exposed to form a pattern (using a hard mask). The photoresist layer may be, for example, an organic spin on layer. A reactive ion etching (RIE) process is performed to form a via in the upper dielectric layer 16, which reaches to the lower cap layer 14.

A similar lithographic and RIE process is used to form a trench in the upper dielectric layer 16. The trench can range from about 250 Å to 5000 Å in thickness, and preferably about half way into the upper dielectric layer 16.

A RIE is formed to open the lower cap layer 14 to the conductive wire 12. A sputter etch can be performed to etch into the conductive material (e.g., copper) of the conductive wire 12. This etching can also increase the depth of the trench. A liner material 18 is deposited in the via and the trench to form a lower liner 18. The lower liner material is deposited over and in contact with the conductive wire 12. The lower liner material can be, for example, tantalum, tantalum nitride, titanium or titanium nitride or Ruthenium. The lower liner material can be deposited using a conventional PVD (physical vapor deposition), CVD (chemical vapor deposition) process or ALD (atmomic layer deposition). The lower liner 18 can range in thickness from about 2 nm to 20 nm.

A copper seed layer 20 is deposited over the lower liner 18. In optional embodiments, copper plating may be performed over the cooper seed layer 20 to form a thicker copper layer. In embodiments, the copper seed layer 20 (or combination of the seed layer and plating) may range from about 25 Å to 700 Å. The copper seed layer 20 is isolated from the conductive wire 12 by the lower liner 18. An upper liner 22 is deposited over the layer 20. The upper liner 22 is about 1 nm to 20 nm and forms a redundant system, effectively sandwiching the copper layer between the lower liner 18 and the upper liner 22. The upper liner 22 may be, for example, tantalum, tantalum nitride, titanium, titanium nitride or Ruthenium. As should be understood by those of skill in the art, the upper liner 22 will provide a redundant system, thus protecting the underlying layer 20 from electromigration failure (e.g., creation of voids), as the layer 20 is sandwiched between two liners 18 and 22.

An upper conductive layer 24 is deposited on the upper liner 22 in a conventional process. For example, a thin copper seed layer is deposited on the upper liner 22 and a conventional copper plating process is used to form the remaining portions of the upper conductive layer 24. The upper conductive layer 24 is separated from the copper layer 20 by the upper liner 22. The upper conductive layer 24 is planarized using a conventional process such as a chemical mechanical processing (CMP). A second (upper) cap layer 26 is deposited over the planarized upper conductive layer 24 to form an M+1 layer. The same processes discussed herein can be used for form an M or M+1 layer.

In embodiments, the horizontal distance (x) between the upper liner 22 and the lower liner 18 can range from 0% of the width to 49% of the width of the trench. Also, in embodiments, the vertical distance (y) between the upper liner 22 and the lower liner 18 can range from 0% to 100% of the height of the trench.

FIG. 2 shows a formation of a void 28 in the upper conductive layer 24 due to electromigration effects. As shown representative, the void 28 is only formed in the upper conductive layer 24, leaving the conductive layer 20 below the upper liner 22 electrically connected. As the lower conductive layer 20 is sandwiched between the liners 18 and 22 and more specifically protected by the upper liner 22, voids will not form (or will form much later) in the lower conductive layer 20. Thus, the upper liner 22 is effective for further improvement of the electromigration resistance of the interconnect system as it ensures the electrical conductivity to the upper conductive layer 24 and the lower conductive layer 20.

More specifically, in this configuration, advantageously, the lower conductive layer 20, e.g., copper, is buried between the upper liner 22 and the lower liner 18, which forms a redundant interconnect. In this way, the redundant mechanism is the basis of the enhanced electromigration resistance of the interconnect. For example, when the copper atoms located at the upper side of the upper liner 22 migrate to create voids, the voids do not form on the lower side of the upper liner 22. Accordingly, even when the voids grow across the upper conductive layer 24, the copper interconnect as a system does not cause any disconnection failure, e.g., electromigration open failure, because the lower conductive layer 20 keeps the conductivity even after the complete disconnection at the upper layer.

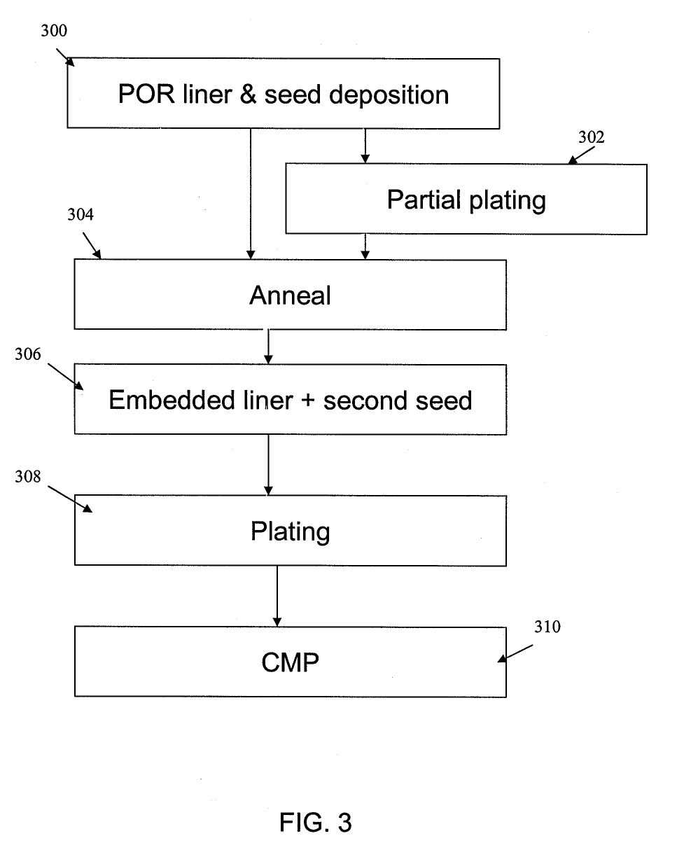

FIG. 3 shows processing steps in accordance with the invention beginning at the first liner 18. At step 300, the lower liner is formed and seed deposition is provided to form a thin copper layer on the lower liner. In an optional step, a partial plating process is provided over the seed deposition layer to form a thicker copper layer. At step 304, an annealing process is provided. At step 306, the upper liner is formed and a second seed layer is deposited to form a thin copper layer (upper conductive layer). A copper plating is performed at step 308 to form the remaining portion of the upper conductive layer. A CMP process is performed to planarize the upper conductive layer at step 310.

If via resistance is an issue, a selective sputter can be done after the embedded liner deposition in which the via liner is removed. As the embedded liner (upper liner)) is thin, the assumption is that the copper polish will not stop on it. Ideal slurry would thus be a low selectivity Cu slurry (e.g. Cabot Y-75)

The methods and structures as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with the structures of the invention) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

While the invention has been described in terms of embodiments, those skilled in the art will recognize that the invention can be practiced with modifications and in the spirit and scope of the appended claims.

1. An interconnect structure, comprising:
a planarized lower dielectric layer;
a lower cap layer on the planarized lower dielectric layer;
a copper material formed in a trench of the planarized lower dielectric layer, below the lower cap layer;
a lower liner extending into a pattern of the lower cap layer and contacting the copper layer;
an upper dielectric layer on the lower cap layer, the upper dielectric layer having a trench and a via extending into the lower cap layer;
a copper layer formed in the trench of the upper dielectric layer and the via extending into the lower cap layer, the copper layer contacting the lower liner in the via of at least the lower cap layer and the trench of the upper dielectric layer;
an upper liner formed over the copper layer, sandwiching the copper layer between the lower liner and the upper liner in the trench of the upper dielectric layer and the via extending into the lower cap layer;
an upper copper layer formed over the upper liner and in the trench of the upper dielectric; and
an upper cap layer on the upper copper layer and the upper dielectric layer, wherein
the copper layer, the upper liner and the upper copper layer are formed in the via, and
the lower liner is formed in the via and extends on the upper dielectric layer over the lower cap layer.

2. The interconnect structure of claim 1, wherein:
the upper liner and the lower liner are made from tantalum, tantalum nitride, titanium or titanium nitride;
the lower liner has a thickness of about 2 nm to 20 nm and the upper liner is has a thickness of about 1 nm to 20 nm;
the lower cap layer is silicon carbide or silicon nitride and has a thickness in a range about 50Å to 1000Å; and
the planarized lower dielectric layer and the upper dielectric layer is a low k or ultra low k dielectric material ranging in thickness from about 1000Å to 10000Å.

3. The interconnect structure of claim 1, wherein the lower liner is formed in the via of the upper dielectric layer and extends on the upper dielectric layer over the lower cap layer.

4. (canceled)

5. The interconnect structure of claim 1, wherein a horizontal distance (x) between the upper liner and the lower liner range from 0% of a width to 49% of the width of the trench.

6. The interconnect structure of claim 1, wherein a vertical distance (y) between the upper liner and the lower liner range from 0% to 100% of a height of the trench.

7. An interconnect structure, comprising:
a lower dielectric layer;
a copper wire formed in a trench of the lower dielectric layer;
a lower cap layer formed over the lower dielectric layer and the copper wire to form an M layer;
an upper dielectric layer formed on the lower cap layer;
a lower metal liner formed in a via of the lower cap layer and the upper dielectric layer and in contact with the copper wire;
a copper layer deposited over the lower metal liner in the via and in a trench of the upper dielectric layer, the copper layer being separated from the copper wire by the lower metal liner in the via and the trench;
an upper metal liner deposited over the copper layer and sandwiching the copper layer between the lower metal liner and the upper metal liner in the via and the trench;
an upper copper layer formed in the trench of the upper dielectric layer and in contact with the upper metal liner, the upper copper layer being separated from the copper layer by the upper metal liner; and
an upper cap layer formed over the upper copper layer and the upper dielectric layer.

8. The interconnect structure of claim 7, wherein:
the upper metal liner has a thickness of about 1 nm to 20 nm and provides a redundancy to the lower metal liner which has a thickness of about 2 nm to 20 nm;
the lower liner and the upper liner are one of tantalum, tantalum nitride, titanium, titanium nitride, and Ruthenium.
the copper layer is about 25Å to 700Å;
the lower dielectric layer and the upper dielectric layer are low k or ultra low k materials each having a thickness ranging from about 1000Å to 10000Å; and
the lower cap layer is silicon nitride or silicon carbide with a thickness from about 50Å to 1000Å.
